(19) United States
(12) Patent Application Publication
(10) Pub. No.: US 2014/0284660 A1
(43) Pub. Date: Sep. 25, 2014

(54) METHOD FOR MANUFACTURING SEMICONDUCTOR WAFER, AND SEMICONDUCTOR WAFER

(71) Applicant: Advanced Power Device Research Association, Yokohama-shi (JP)

(72) Inventors: Ryohei MAKINO, Kanagawa (JP); Takao KUMADA, Kanagawa (JP); Masaharu EDO, Kanagawa (JP); Keishi TAKAKI, Kanagawa (JP)

(21) Appl. No.: 13/938,749

(22) Filed: Jul. 10, 2013

(30) Foreign Application Priority Data
Mar. 22, 2013 (JP) 2013-059827

(51) Int. Cl. H01L 21/78; H01L 29/205

(52) U.S. Cl. CPC H01L 21/78; H01L 29/205
USPC 257/190; 438/460

(57) ABSTRACT

A method for manufacturing a semiconductor wafer includes the steps of forming, on a first principal surface of a substrate, a compound semiconductor layer different in kind from the substrate, and removing, by etching, a part of the compound semiconductor layer. The part of the compound semiconductor layer is formed on an outer peripheral portion of the first principal surface of the substrate.

### CROSS-REFERENCE TO RELATED APPLICATION

This application is based upon and claims the benefit of priority from Japanese Patent Application No. 2013-059827 filed in Japan on Mar. 22, 2013, the entire contents of which are incorporated herein by reference.

### BACKGROUND

1. Technical Field

The disclosure relates to a method for manufacturing a semiconductor wafer in which a compound semiconductor layer is formed on a substrate, and relates to the semiconductor wafer.

2. Related Art

When a compound semiconductor layer that is different in kind or composition from a substrate is formed on the substrate to manufacture a semiconductor wafer for manufacturing a semiconductor device, cracks attributed to stress may occur in an outer peripheral portion of the semiconductor wafer. In particular, it is known that when a gallium nitride (GaN)-based compound semiconductor layer is formed on a silicon substrate, stress is liable to occur in the semiconductor wafer because lattice constants of a silicon crystal and a GaN-based compound semiconductor crystal are considerably different from each other, and hence the cracks attributed to the stress are liable to occur in the outer peripheral portion of the semiconductor wafer.

The occurrence of cracks in the outer peripheral portion of the semiconductor wafer may increase if stress is further applied to the semiconductor wafer in the manufacturing process of the semiconductor device, thus lowering quality or yield of the semiconductor device. In particular, when the GaN-based compound semiconductor layer is formed on the silicon substrate to manufacture a power semiconductor device used in a power conversion field, a step of reducing thickness of the silicon substrate is performed after the compound semiconductor layer is formed on the silicon substrate to manufacture the semiconductor wafer. In the step of reducing the thickness of the silicon substrate, a principal surface of the semiconductor wafer that is opposite to a surface where the compound semiconductor layer is formed (i.e., a back side surface of the silicon substrate) is polished or ground.

During or after the step of reducing the thickness of the substrate, the thickness of the silicon substrate becomes thin, and hence stress due to a deformation such as a warp is liable to be applied to the semiconductor wafer. Therefore, a crack in the outer peripheral portion of the semiconductor wafer may cause damage such as a fracture or chipping of the semiconductor wafer. For example, it is known that when polishing or grinding the back side surface of the semiconductor wafer in which the GaN-based compound semiconductor layer is formed on the silicon substrate having a diameter of 4 inches (approximately 100 mm) or larger, the semiconductor wafer may fracture during or immediately after this step.

In order to avoid this situation, there is a method including a division step of dividing the semiconductor wafer into rectangular parts or sector parts by dicing before the step of polishing or grinding the back side surface of the semiconductor wafer. However, in this method, the additional division step prior to the polishing or grinding step creates rising costs due to an increase in the number of steps. Furthermore, the additional division step increases the number of pieces into which the semiconductor wafer is divided, and hence steps subsequent to the division step (that is, a polishing or grinding step, a step of forming electrodes on the back side surface of the substrate, and a step of dicing the semiconductor wafer for dividing into chips) cause an increase in cost.

Japanese Patent Application Laid-open No. 2012-36030 discloses a method for suppressing occurrence of cracks attributed to stress on an outer peripheral portion of a semiconductor wafer in manufacturing a semiconductor device having a GaN-based compound semiconductor layer on a silicon substrate. In the method described in Japanese Patent Application Laid-open No. 2012-36030, before forming a GaN-based compound semiconductor layer on a silicon substrate, a growth inhibition layer is formed for inhibiting the formation of the GaN-based compound semiconductor layer on the outer peripheral portion of the surface of the silicon substrate where the GaN-based compound semiconductor layer is supposed to be formed. According to Japanese Patent Application Laid-open No. 2012-36030, it is found that the cracks occurs on a compound semiconductor layer on a tapered portion provided in the outer peripheral region of the substrate, and thus the occurrence of cracks in the outer peripheral region of the semiconductor wafer can be suppressed by the above-mentioned method.

However, in the method described in Japanese Patent Application Laid-open No. 2012-36030, the additional step of forming the growth inhibition layer causes an increase in cost due to an increase in the number of steps. Furthermore, the step may result in change or modification of the surface conditions such as contamination due to impurities on the surface of the substrate before the compound semiconductor layer is formed. Furthermore, in the step of forming the compound semiconductor layer, various situations may occur due to the formation of the growth inhibition layer on the outer peripheral portion of the substrate. For example, deficiency in material of the growth inhibition layer may lead to contamination or particles in the compound semiconductor layer and in the manufacturing device thereof. Furthermore, formation of discontinuous crystalline regions of the compound semiconductor layer in the vicinity of an end portion of the growth inhibition layer on the substrate may cause some kind of adverse effects. In addition, the growth inhibition layer may affect the deformation of the semiconductor wafer due to the change in temperature of the substrate while forming the compound semiconductor layer or may disturb the monitoring or control of the state of forming the compound semiconductor layer.

Accordingly, there is a need to provide a method for manufacturing a semiconductor wafer that is capable of preferably suppressing the occurrence of cracks in the outer peripheral portion of the semiconductor wafer, and the semiconductor wafer.

### SUMMARY

In accordance with some embodiments, a semiconductor wafer and a method for manufacturing the same are presented.

In some embodiments, a method for manufacturing a semiconductor wafer includes the steps of: (a) forming, on a first principal surface of a substrate, a compound semiconductor layer different in kind from the substrate; and (b) removing, by etching, a part of the compound semiconductor layer. The part of the compound semiconductor layer is formed on an outer peripheral portion of the first principal surface of the substrate.

In some embodiments, a method for manufacturing a semiconductor wafer includes the step of (a) forming, on a first principal surface of a substrate, a compound semiconductor layer different in kind from the substrate. In step (a), the compound semiconductor layer is formed while masking an outer peripheral portion of the first principal surface of the substrate.

In some embodiments, a semiconductor wafer includes a substrate, and a compound semiconductor layer formed on a principal surface of the substrate. The compound semiconductor layer is different in kind from the substrate. On an outer peripheral portion of the principal surface of the substrate, a region where the compound semiconductor layer is partially removed by etching is formed.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIGS. 1A and 1B are schematic views of an exemplary semiconductor wafer manufactured by a manufacturing method according to a first embodiment;

FIG. 2 is a schematic view of another exemplary semiconductor wafer manufactured by the manufacturing method according to the first embodiment;

FIGS. 3A to 3F are explanatory views of the manufacturing method according to the first embodiment; and

FIGS. 4A to 4C are explanatory views of a manufacturing method according to a second embodiment.

### DETAILED DESCRIPTION

Exemplary embodiments of a semiconductor wafer and a method for manufacturing the same will be explained in detail below with reference to the accompanying drawings. The present invention is not limited to these embodiments. Furthermore, in the respective drawings, parts identical to each other or corresponding to each other are appropriately given same numerals. In addition, it is necessary to pay attention to the following; that is, each drawing is schematically illustrated and the relation between dimensions of the respective parts may be different to the cases of actual parts. In the mutual relation between the drawings also, the drawings may include parts each having different relation between dimensions thereof or different ratio of the dimensions thereof.

### First Embodiment

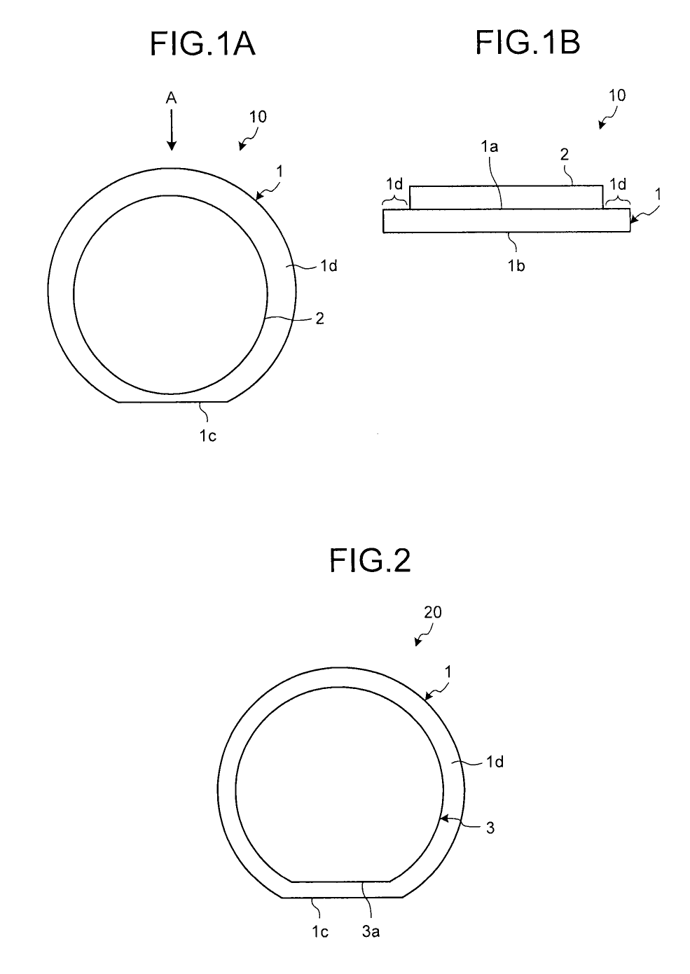

FIGS. 1A and 1B are schematic views of an exemplary semiconductor wafer that can be manufactured by a manufacturing method according to a first embodiment. FIG. 1A is a plan view and FIG. 1B is a side view viewed from an arrow A in FIG. 1A. As illustrated in FIGS. 1A and 1B, a semiconductor wafer 10 includes a substrate 1 and a compound semiconductor layer 2.

The substrate 1 is, for example, a silicon (Si) substrate and has principal surfaces 1a and 1b, and an orientation flat (OF) portion 1c.

The compound semiconductor layer 2 includes a compound semiconductor different in kind from the substrate 1, such as, gallium nitride (GaN), aluminum gallium nitride (AlGaN), indium nitride (InN) or the like, or III-V nitride compound semiconductor containing mixed crystals thereof. Here, “different in kind from the substrate 1” means that the compound semiconductor layer 2 contains an element different from that of the substrate 1, the compound semiconductor layer 2 has a different lattice constant from that of the substrate 1, or the compound semiconductor layer 2 is made of the same materials as that the substrate 1 but a different composition from that of the substrate 1. In the first embodiment, the compound semiconductor layer 2 includes a compound semiconductor layer having a monolayer or multilayer structure expressed as AlₓGa₁₋ₓN (0≦x≦1).

On an outer peripheral portion on the principal surface 1a of the substrate 1, a region 1d is formed where the compound semiconductor layer 2 is partially removed by etching over the entire outer peripheral portion. With this structure, the occurrence of cracks in the compound semiconductor layer 2 on an outer peripheral region of the semiconductor wafer 10 is suppressed. Furthermore, in the semiconductor wafer 10, a growth inhibition layer is not formed, and thus various situations occurring when the growth inhibition layer is formed can be avoided.

In the semiconductor wafer 10, the compound semiconductor layer 2 has a circular shape as viewed from above. Hence, the width of the region 1d varies depending on the position in the circumferential direction because of the OF portion 1c, and the width is narrow in the OF portion 1c.

Since the compound semiconductor layer 2 is formed in a circular shape as viewed from above, stress occurring in the outer periphery of the semiconductor wafer 10 is equalized along the outer periphery. This further enhances an effect of suppressing the occurrence of cracks in the outer peripheral portion of the semiconductor wafer and the warp of the semiconductor wafer.

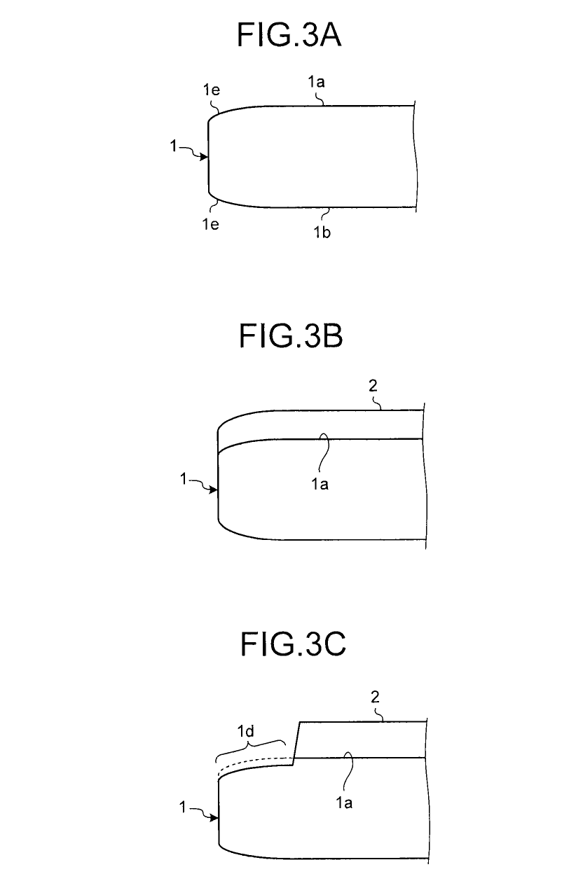

However, the shape of the compound semiconductor layer is not limited to the circular shape. FIG. 2 is a schematic view of another example of the semiconductor wafer that can be manufactured by the manufacturing method according to the first embodiment. A semiconductor wafer 20 illustrated in FIG. 2 includes a compound semiconductor layer 3 instead of the compound semiconductor layer 2 of the semiconductor wafer 10. In the semiconductor wafer 20, the width of the region 1d formed over the entire outer periphery thereof is approximately constant irrespective of the position in the circumferential direction. A part of an outer edge of the compound semiconductor layer 3 is in parallel with the OF portion 1c where the part of the outer edge faces the OF portion 1c. Thus, a part of an outer edge 3a of the compound semiconductor layer 3 may be formed in parallel with the OF portion 1c where the part of the outer edge 3a faces the OF portion 1c.

In this example, an etching region where the compound semiconductor layer 3 is to be etched is designed to have a width required for eliminating cracks, so that a non-etched region can be enlarged to a maximum extent and many chips can be manufactured from a single wafer. Furthermore, even in the OF portion 1c, the region 1d where the compound semiconductor layer 3 is etched has the same width as that of a circular arc portion, and hence the occurrence of cracks in the OF portion 1c can be suppressed to the same degree as that in the circular arc portion.

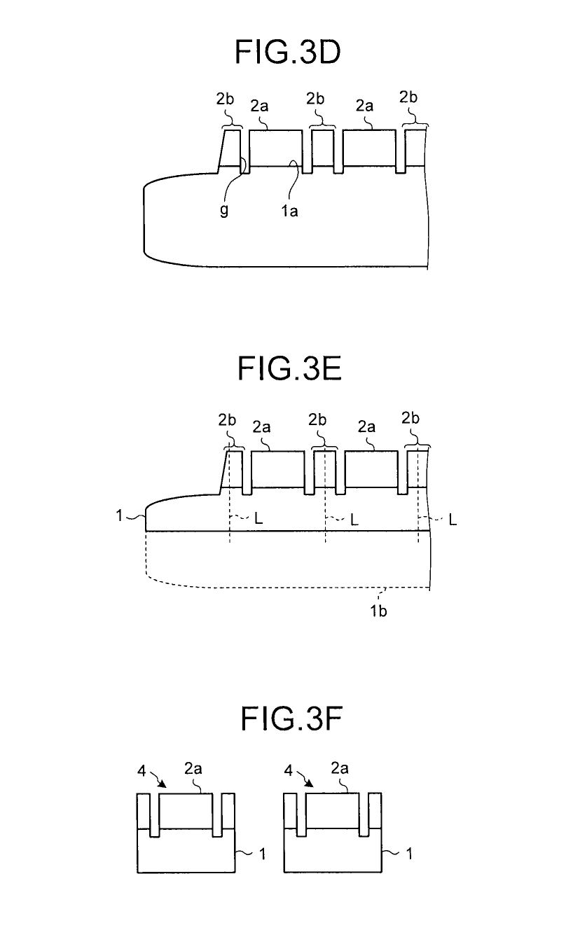

Next, a manufacturing method of the semiconductor wafer 10 according to the first embodiment will be explained. FIGS. 3A to 3F are explanatory views of the manufacturing method according to the first embodiment.

First of all, as illustrated in FIG. 3A, a substrate 1 is provided. The substrate 1 includes the principal surfaces 1a and 1b. Each of the principal surfaces 1a and 1b is flat in a region from the center to the periphery thereof, and includes a tapered portion 1e on an outer peripheral portion thereof. The tapered portion 1e is formed by, for example, chamfering, and is inclined so that the thickness of the substrate 1 is reduced toward the outer peripheral side thereof.

Next, as illustrated in FIG. 3B, the compound semiconductor layer 2 is formed on the principal surface 1a of the substrate 1. The compound semiconductor layer 2 is formed over a region from the flat portion to the tapered portion 1e by a chemical vapor deposition method (CVD) such as a metal organic chemical vapor deposition method (MOCVD) or a molecular beam epitaxy method (MBE).

Next, as illustrated in FIG. 3C, the compound semiconductor layer 2 formed on the outer peripheral portion of the principal surface 1a is removed by etching over the entire outer periphery of the principal surface. In this manner, the region 1d is formed. The process of etching can be performed by patterning with the use of an etching technique such as well-known wet etching or dry etching in which a technique such as a photolithographic technique is used.

Because the region 1d is formed in this manner, the occurrence of cracks in the outer peripheral portion of the semiconductor wafer 10 can be suppressed. Furthermore, it is possible to prevent the expansion of cracks in the subsequent manufacturing process of a semiconductor device and the lowering of quality or yield of the semiconductor device.

In the process of etching, it is acceptable that the depth of etching reaches only a part of the thickness of the compound semiconductor layer 2. However, as illustrated in FIG. 3C, it is preferable that a part of the principal surface 1a be removed by overetching in the process of etching or that the depth of etching reach the thickness of the compound semiconductor layer 2 so as not to remove the principal surface 1a by overetching. Such an etching process further enhances the effect of suppressing the occurrence of cracks. If the depth of etching reaches only a part of the thickness of the compound semiconductor layer 2, the depth of etching is set so as to obtain the effect of suppressing the occurrence of cracks in the outer peripheral portion of the semiconductor wafer 10.

Preferably, the width of the region 1d covers at least the tapered portion 1e of the substrate 1 extending from the outer edge toward the center region of the substrate 1. Alternatively, the region 1d may include a part of the flat portion of the substrate 1. It is noted that if the width of the region 1d is excessively increased, a region of the semiconductor wafer that can be effectively used for manufacturing a semiconductor device becomes small. Therefore, it is preferable that the width of the region 1d is limited to a range including the tapered portion 1e which is necessary and sufficient to eliminate the influence of cracks in the outer peripheral portion. The width of the region 1d is, for example, in the range from 1 mm to 20 mm.

When the compound semiconductor layer 2 is formed on the principal surface 1a of the substrate 1, a crystal orientation in the tapered portion 1e and a crystal orientation in the flat portion are different from each other. Accordingly, the compound semiconductor layer 2 based on both of the crystal orientation in the flat portion and the crystal orientation in the tapered portion 1e is formed on the substrate 1. The compound semiconductor layer 2 on the tapered portion 1e is different in crystal orientation, crystallinity, growth rate, or the like from the compound semiconductor layer 2 on the flat portion, and hence stress is liable to occur in the vicinity of the tapered portion 1e. Alternatively, stress is liable to occur at the interface between the compound semiconductor layer 2 on the flat portion and the compound semiconductor layer 2 on the tapered portion 1e, which is considered to be one of the factors of the occurrence of cracks in the outer peripheral region of the semiconductor wafer 10.

In contrast, in the manufacturing method according to the first embodiment, because the compound semiconductor layer 2 formed on the tapered portion 1e is removed, only the homogeneous compound semiconductor layer 2 based on the crystal orientation ((111) plane, for example) of the flat portion remains on the substrate 1. Accordingly, the stress is unlikely to occur in the outer peripheral portion of the semiconductor wafer 10. Therefore, the occurrence of cracks in the outer peripheral portion of the semiconductor wafer 10 can be further suppressed. In addition, even if the cracks occur in the compound semiconductor layer 2 on the tapered portion 1e, the compound semiconductor layer 2 on the tapered portion 1e is removed, and thus the expansion of the cracks is prevented.

Next, in the first embodiment, as illustrated in FIG. 3D, a semiconductor device forming process including a plurality of processes for forming a specified semiconductor device in the compound semiconductor layer 2 is performed. Examples of the semiconductor device forming process include a forming process by etching for forming a recessed portion and the like, an electrode forming process, an element isolation process, an insulating film forming process, and a protective film forming process. In the first embodiment, semiconductor devices 2a are formed at the semiconductor device forming process, and the semiconductor devices 2a are isolated by grooves g. Dicing regions 2b for dicing are formed between the semiconductor devices 2a.

Any one of the plurality of processes in the semiconductor device forming process in FIG. 3D and the etching process in FIG. 3C may be exchanged for one another. Alternatively, any one of the plurality of processes of the semiconductor device forming process in FIG. 3D and the etching process in FIG. 3C may be simultaneously performed.

For example, during a single etching process, both of the forming process of the region 1d by removing the compound semiconductor layer 2 and the element isolation process for forming the grooves g are performed. Thus, if both of the forming process of the region 1d and the commonly-performed process to form the semiconductor device are simultaneously performed, the increase in manufacturing cost due to the increase in the number of steps or processes can be suppressed or prevented.

In this case, the element isolation process may be an etching process including a photolithography process using a mask having such a pattern that the region 1d is formed by this process. Alternatively, the element isolation process may be another etching process including a process of removing, after a resist for the element isolation process is applied to the compound semiconductor layer 2, the resist applied to the outer peripheral portion on which the region 1d is to be formed, before the resist solidifies.

Next, as illustrated in FIG. 3E, a thinning process is performed to reduce the thickness of the substrate 1 by polishing or grinding the principal surface 1b of the substrate 1, which is different from the principal surface 1a on which the compound semiconductor layer 2 is formed.

Thus, in particular, when the GaN-based compound semiconductor layer is formed on the silicon substrate to manufacture a power semiconductor device used in a power conversion field, the thinning process of reducing the thickness of the silicon substrate is performed after the compound semiconductor layer is formed on the silicon substrate to manufacture the semiconductor wafer. In the thinning process, the principal surface of the semiconductor wafer, which is opposite to a surface where the compound semiconductor layer is formed (i.e., a back side surface of the silicon substrate), is polished or ground.

As described above, it is known that the semiconductor wafer fractures during or immediately after the thinning process. In order to avoid this situation, there is a method including a division step of dividing the semiconductor wafer into rectangular parts or sector parts by dicing before the step of polishing or grinding the back side surface of the semiconductor wafer. However, in this method, the additional division step prior to the polishing or grinding step creates rising costs due to an increase in the number of steps or processes.

In contrast, because the region 1d is formed in the first embodiment, it is unnecessary to divide the semiconductor wafer 10 into rectangular parts or sector parts by dicing before the process of polishing or grinding the back side surface of the semiconductor wafer 10. Accordingly, the occurrence of cracks can be suppressed in the outer peripheral region of the semiconductor wafer 10 at low cost.

Here, as the method of polishing or grinding, a polishing method known as a mirror polishing method such as a mechanical polishing method and a chemical mechanical polishing method (CMP), a grinding method known as a back grind (BG) method, or the combination of the above mentioned methods can be employed. Furthermore, when polishing or grinding is performed, the size of the substrate 1 (“size” means diameter, for example, when the substrate is formed in a circular shape or substantially circular shape) is not particularly limited. However, it may be possible to employ a size of 4 inches or larger of a substrate, which is liable to fracture by the polishing or grinding process when the method of the first embodiment is not applied. Furthermore, examples of the shape of the substrate 1 include, but are not limited to a circular shape or a substantially circular shape. In addition, the thickness of the semiconductor wafer 10 before and after polishing or grinding is not limited. For example, it is possible to reduce the thickness of the semiconductor wafer 10 having a thickness of 500 μm or larger before polishing or grinding, to 500 μm or smaller.

Thereafter, a dicing process is performed along dicing lines L on the dicing regions 2b illustrated in FIG. 3E, and the semiconductor wafer 10 is cut for each semiconductor device 2a to be isolated as illustrated in FIG. 3F. In this manner, the semiconductor wafer 10 is divided into semiconductor chips 4, each of which includes the semiconductor device 2a formed on the substrate 1.

As described above, by the manufacturing method in the first embodiment, the occurrence of cracks in the outer peripheral region of the semiconductor wafer 10 can be suppressed at low cost, and the high-quality, high-yield semiconductor device 2a and the semiconductor chip 4 including the semiconductor device 2a can be obtained.

### Second Embodiment

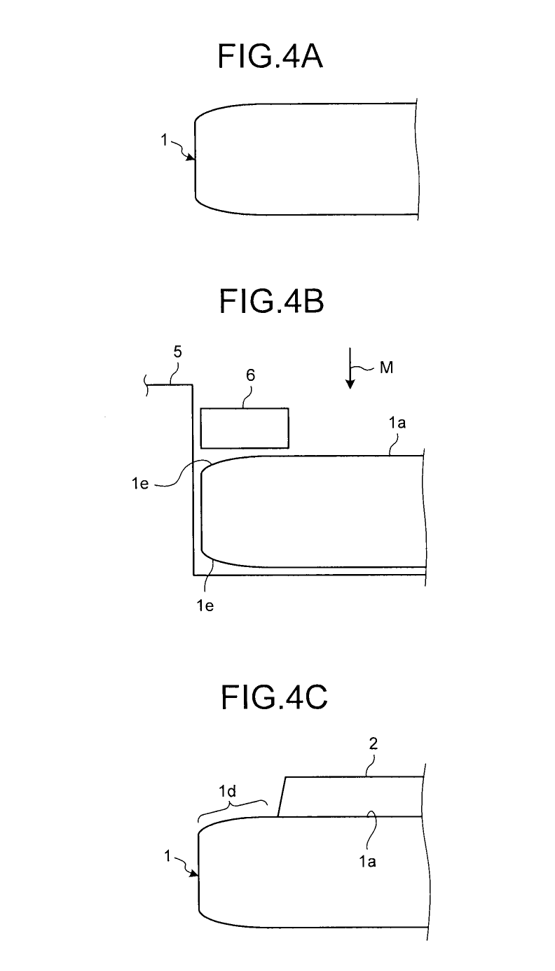

In a second embodiment, the region 1d is formed after the compound semiconductor layer 2 is formed, by removing the compound semiconductor layer 2 on the region 1d, in common with the first embodiment. When forming the compound semiconductor layer 2 on the principal surface 1a, the region 1d is masked so that the compound semiconductor layer 2 is not formed on the region 1d from the beginning. Hereinafter, a manufacturing method of the semiconductor wafer 10 according to the second embodiment will be explained. FIGS. 4A to 4C are explanatory views of the manufacturing method according to the second embodiment.

First of all, the substrate 1 is provided in common with the first embodiment, as illustrated in FIG. 4A.

Next, as illustrated in FIG. 4B, the substrate 1 is loaded into a crystal growth apparatus 5. Furthermore, a mask member 6 is arranged for masking the outer peripheral portion of the principal surface 1a of the substrate 1 that includes at least the tapered portion 1e, over the whole circumference of the substrate 1. Next, while the outer peripheral portion of the principal surface 1a is masked, a material substance M of the compound semiconductor layer 2 is supplied to the principal surface 1a. With the processes, as illustrated in FIG. 4C, it is possible to form the semiconductor wafer 10 having the compound semiconductor layer 2 on the principal surface 1a of the substrate 1 and having the region 1d as a non-forming region where the compound semiconductor layer 2 is not formed on the outer peripheral portion of the principal surface 1a of the substrate 1.

The mask member 6 has a shape capable of masking the outer peripheral portion of the principal surface 1a of the substrate 1 over the whole circumference of the substrate 1; for example, an annular shape. Preferably, the mask member 6 is made of material such as ceramic material that is durable under environmental conditions such as heat in the process of forming the compound semiconductor layer 2. Furthermore, a shape, structure and arrangement of the mask member 6 can be such that the mask member 6 is capable of stably masking at least the tapered portion 1e of the outer peripheral portion of the substrate 1 over the whole circumference of the substrate 1 during the process of forming the compound semiconductor layer 2 to form the region 1d.

In addition, the mask member 6 can be arranged so as to be brought into contact with the principal surface 1a of the substrate 1 to retain the substrate 1, or can be arranged above the principal surface 1a of the substrate 1 so as not to be brought into contact with the principal surface 1a.

Here, thereafter, in common with the first embodiment, the processes illustrated in FIGS. 3D to 3F can be appropriately performed, and the semiconductor chip 4 in which the semiconductor device 2a is formed on the substrate 1 can be formed.

According to the manufacturing method of the second embodiment, in common with the first embodiment, the occurrence of cracks can be suppressed in the outer peripheral region of the semiconductor wafer 10 at low cost. In addition, the high-quality, high-yield semiconductor device 2a and the semiconductor chip 4 including the semiconductor device 2a can be obtained.

According to some embodiments, the occurrence of cracks in the outer peripheral portion of the semiconductor wafer can be preferably suppressed.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A method for manufacturing a semiconductor wafer, comprising the steps of:
(a) forming, on a first principal surface of a substrate, a compound semiconductor layer different in kind from the substrate; and
(b) removing, by etching, a part of the compound semiconductor layer, the part of the compound semiconductor layer being formed on an outer peripheral portion of the first principal surface of the substrate.

2. The method according to claim 1, further comprising the step of:
(c) performing a plurality of processes to form semiconductor devices in the compound semiconductor layer, wherein
step (b) is performed while performing any one of the plurality of processes.

3. The method according to claim 2, wherein step (b) is performed while isolating the semiconductor devices.

4. The method according to claim 1, wherein the substrate is a silicon substrate.

5. The method according to claim 1, wherein the compound semiconductor layer contains a nitride-based compound semiconductor.

6. The method according to claim 1, further comprising the step of:
(d) reducing thickness of the substrate by polishing or grinding a second principal surface of the substrate that is different from the first principal surface on which the compound semiconductor layer is formed.

7. The method according to claim 6, further comprising the step of:
(e) dividing the semiconductor wafer into a plurality of chips after step (d).

8. A method for manufacturing a semiconductor wafer, comprising the step of:
(a) forming, on a first principal surface of a substrate, a compound semiconductor layer different in kind from the substrate, wherein
in step (a), the compound semiconductor layer is formed while masking an outer peripheral portion of the first principal surface of the substrate.

9. The method according to claim 8, wherein the substrate is a silicon substrate.

10. The method according to claim 8, wherein the compound semiconductor layer contains a nitride-based compound semiconductor.

11. The method according to claim 8, further comprising the step of:
(d) reducing thickness of the substrate by polishing or grinding a second principal surface of the substrate that is different from the first principal surface on which the compound semiconductor layer is formed.

12. The method according to claim 11, further comprising the step of:
(e) dividing the semiconductor wafer into a plurality of chips after step (d).

13. A semiconductor wafer comprising:
a substrate; and
a compound semiconductor layer formed on a principal surface of the substrate, the compound semiconductor layer being different in kind from the substrate, wherein
on an outer peripheral portion of the principal surface of the substrate, a region where the compound semiconductor layer is partially removed by etching is formed.
